(19) United States
(12) Patent Application Publication
(10) Pub. No.: US 2008/0038479 A1
(43) Pub. Date: Feb. 14, 2008

(54) Apparatus and method for processing a substrate

(76) Inventor: Yasuaki Orihara, Niigata (JP)

Correspondence Address: MCDERMOTT WILL & EMERY LLP, 600 13TH STREET, NW, WASHINGTON, DC, 20005-3096, US

(21) Appl. No.: 11/878,692

(22) Filed: Jul. 26, 2007

(30) Foreign Application Priority Data
Aug. 11, 2006 (JP) 2006-219278

(51) Int. Cl. B05D 3/06; C23C 14/00

(52) U.S. Cl. 427/553; 118/50.1

(57) ABSTRACT

An apparatus for processing a substrate according to the present invention comprises a lamp unit heating the substrate placed in the chamber at a position facing the substrate. A transmission window constituting the top wall of the chamber and transmitting light emitted from the lamp unit is provided between the chamber and the lamp unit. A window assembly having a wall constituted by the transmission window is provided at the lamp unit side of the transmission window. An evacuation unit is connected to the window assembly. A pressure control unit controls the evacuation unit to maintain the internal pressure of the window assembly at a specific pressure. In this way, multiple substrates are subject to a significantly uniform substrate processing when they are processed in succession.

### CROSS-REFERENCE TO RELATED APPLICATION

The present application claims the benefit of patent application number 2006-219278, filed in Japan on Aug. 11, 2006, the subject matter of which is incorporated herein by reference.

### BACKGROUND OF THE INVENTION

1. Field of the Invention

The present invention relates to an apparatus and method for processing a substrate under lamp heating.

2. Description of the Related Art

As finer element patterns have come to be recently used to constitute semiconductor devices, it has been necessary to form thin gate insulating films or shallow impurity diffusion regions in a uniform and stable manner without reducing throughput. Therefore, substrate processing apparatuses of the RTP (rapid thermal process) type are used in the semiconductor device production process, in which short-time thermal processing is performed in a single-wafer process. Among such substrate processing apparatuses, a lamp RTP apparatus has been developed and extensively used, in which a semiconductor substrate is processed while being heated by energy emitted from substrate-heating lamps.

FIG. 5 is a cross-sectional view showing a lamp RTP apparatus 100 described above (hereafter referred to as a substrate processing apparatus 100). The substrate processing apparatus 100 comprises a lamp unit 2 in which multiple tungsten halogen lamps are arranged above a cylindrical chamber 3 in which a substrate is processed via a window assembly 4.

The chamber 3 is provided with a gas inlet 11 for introducing a process gas into the chamber 3 on a sidewall and a gas outlet 12 for discharging the gas from the chamber 3 on the sidewall opposite to the gas inlet 11. For example, when a film of a specific material such as an oxide or nitride film is formed on a substrate 13 at elevated temperatures, a material gas corresponding to the material film is introduced through the gas inlet 11. When the substrate 13 implanted with impurities by ion implantation is annealed for activation, an inert gas such as N₂ or Ar gas is introduced through the gas inlet 11.

A support ring 9 made of a heat-resistant material such as silicon carbide and having an inner diameter slightly smaller than the diameter of the substrate 13 to be processed is provided in a horizontal plane within the chamber 3. The support ring 9 is supported by a cylindrical rotary cylinder 10 vertically protruding from the bottom surface of the chamber 3. The edge of the substrate 13 rests on the inner fringe of the support ring 9. The rotary cylinder 10 is supported by the bottom surface of the chamber 3 via a bearing (not shown) that is rotatable in a horizontal plane. The substrate 13 is processed while rotated. The substrate 13 is loaded/unloaded, for example, through a not-shown substrate gateway provided on a sidewall of the chamber 3 and opened/closed at any time.

Multiple radiation temperature sensors 14 consisting of optical fiber probes and arranged at proper intervals in a radial direction of the substrate 13 are exposed from the bottom of the chamber 3 inside the rotary cylinder 10 at one end and connected to not-shown thermometers such as pyrometers at the other end. Based on light radiated from the bottom surface of the substrate 13 (radiant heat), the surface temperature of the substrate in process is measured across the substrate from the center to the periphery thereof. A temperature control unit 15 controls the output power of the each lamp in the lamp unit 2 based on the measurements to achieve uniform temperatures across the substrate 13 from the center to the periphery thereof.

The window assembly 4 comprises multiple optical pipes 5, an upper quartz plate 6 and a lower quartz plate 7. The optical pipes 5 are fixed between the upper and lower quartz plates 6 and 7 at positions corresponding to the respective lamps in the lamp unit 2. The optical pipes 5 transfer light emitted from the respective lamps to the chamber 3 without diffusion. Small grooves (or recesses) are formed on the surfaces of the upper and lower quartz plates 6 and 7 inside the window assembly 4 for communication between the optical pipes 5. Therefore, all optical pipes 5 can be vacuumed by discharging the air through an evacuation duct 8 in communication with one of the optical pipes 5.

With the above structure, the window assembly 4 can be vacuumed to have an internal pressure equal to or lower than that of the chamber 3 for the substrate processing. In this way, the lower quartz plate 7 is not drawn into the chamber 3 and damaged while the substrate is processed in the vacuumed chamber 3, which likely occurs when the window assembly 4 has a higher internal pressure than that of the chamber 3. When the window assembly 4 has a lower internal pressure than that of the chamber 3, the multiple optical pipes 5 support the lower quartz plate 7; therefore, the quartz plate 7 is not drawn into the window assembly 4 and damaged.

Furthermore, with the above structure, the lower quartz plate 7 that practically seals the top wall of the chamber 3 is allowed to have a significantly small thickness. Consequently, light emitted from the lamps is less attenuated by the lower quartz plate 7 before reaching the substrate 13.

As techniques for forming a gate oxide film or a protection oxide film using the above apparatus, there are RTO (rapid thermal oxidation) in which the lamp heating is performed while the chamber 3 is filled with an oxidizing gas and ISSG (in situ steam generation) oxidization in which the lamp heating is performed while the chamber 3 is filled with an oxidizing gas and hydrogen gas (for example, see the Japanese Laid-Open Patent Application Publication No. 2001-527279). Particularly, ISSG oxidation is extensively used because high quality gate oxide films can be formed.

In the ISSG oxidation, the oxidizing gas and hydrogen gas are introduced into the chamber 3 through the gas inlet 11 while the changer 3 is vacuumed (for example, to 1 to 50 Torr). In this state, the substrate 13 is heated by the lamp heating. Then, the oxidizing gas and hydrogen gas directly react at the surface of the substrate 13 and produce oxygen radicals and H₂O on the surface of the substrate 13. As a result, the surface of the substrate 13 is oxidized.

However, when substrates are successively processed under the lamp heating, there is the problem that thickness of the oxide film on the first processed substrate and thickness of the oxide films on the second processed substrate and thereafter are different, because the temperature profile within the chamber 3 during the process of the first substrate is different from the temperature profile within the chamber 3 during the process of the second substrate and thereafter. In order to resolve this problem, a technique to preheat the interior of the chamber 3 before the oxidization process starts has been proposed (for example, see the Japanese Laid-Open Patent Application Publication No. 2005-175192).

### SUMMARY OF THE INVENTION

The difference in the film thickness between the first substrate and thereafter can be reduced using the technique to preheat the interior of the chamber before the oxidization process starts. However, even if this technique is used, for example, when a relatively large number of, for example 25, substrates 13 are processed in succession, the oxide films of the first processed substrate and the 25th processed substrate have slightly different thicknesses (for example, approximately 0.2 nm). This is a very small difference in thickness. However, in case of forming ultrathin gate oxide films, the small difference in thickness largely changes the electrical properties of the semiconductor devices.

The inventor of the present invention has reviewed the phenomenon that the thickness of the oxide film is increased as the number of times of the substrate processing is increased and found that this phenomenon occurs because it is more difficult for the components of the chamber 3 (particularly the lower quartz plate) to radiate heat during the lamp heating under reduced pressure than under the atmospheric pressure (760 Torr). Under reduced (vacuumed) pressure, heat radiation by convection of gaseous molecules occurs less than under the atmospheric pressure and heat conduction via gaseous molecules is more dominant. Then, the heat radiation rate is lower under reduced pressure than under the atmospheric pressure. Therefore, the heat radiation rate of the components within the chamber 3 is reduced. The components within the chamber 3 gradually accumulate heat therein and raise the ambient temperature within the chamber 3 according to the number of performed substrate processings. Consequently, the oxidation rate is gradually increased according to the number of the performed substrate processings.

Particularly, in the substrate processing apparatus 100 having the window assembly 4 as shown in FIG. 5, the interior of the window assembly 4 is continuously vacuumed and the internal pressures is maintained, for example, at 2 Torr or lower. Therefore, at the surface of the lower quartz plate 7 heated by the lamp unit 2, heat radiation due to convection of gaseous molecules occurs less than under the atmospheric pressure and heat accumulates. Furthermore, in the successive substrate processings in which the temperature of the lamps is raised to a specific value for each substrate processing while the oxidizing gas is introduced within the chamber 3, heat radiated from the components within the chamber 3 (mainly the substrate 13 and support ring 9) heated by the lamps also causes the lower quartz plate 7 to accumulate heat. Also, raising the ambient temperature near the surface of the substrate 13 and, consequently, increasing the oxidization rate.

As shown in FIG. 5, in the prior art substrate processing apparatus 100, the temperature of the substrate 13 is controlled for a specific temperature based on the temperature of the bottom surface of the substrate 13 measured by the radiation temperature sensors 14. Therefore, in the prior art substrate processing apparatus 100, the temperature of the ambient atmosphere in contact with or in the vicinity of the front side of the substrate 13 is not measured or controlled. Then, the rise in the ambient temperature due to the components within the chamber cannot be prevented.

The present invention is proposed in view of the prior art circumstances and the purpose of the present invention is to provide a substrate processing apparatus and substrate processing method in which two or more substrates are subject to a uniform substrate processing even when they are processed in succession.

In order to resolve the above problem with the prior art, the present invention adopts the following means. A substrate processing apparatus of the present invention comprises a chamber in which a substrate is placed. A lamp unit for heating the substrate placed in the chamber is provided at a position facing the substrate placed in the chamber. A transmission window constituting a wall of the chamber and transmitting light emitted from the lamp unit is provided between the chamber and the lamp unit. At the lamp unit side of the transmission window, a decompression room having a wall constituted by the transmission window is provided. An evacuation unit is connected to the decompression room. A pressure control unit controls the evacuation unit to maintain the pressure within the decompression room at a specific pressure.

With the above structure, the internal pressure of the decompression room can be maintained at a specific pressure independent of the internal pressure of the chamber enabling the heat radiation rate of the transmission window to be changed. Therefore, the heat accumulation in the transmission window during the successive substrate processings can be reduced. Then, the ambient temperature around the surface of each substrate is fixed between each substrate processing. Consequently, the substrates are subject to a uniform substrate processing.

In the above structure, the decompression room can comprise a wall that transmits light emitted from the lamp unit at the opposing position to the transmission window and the lamp unit is provided on the exterior surface of the wall. Alternatively, the decompression room can be provided within the lamp unit. It is preferable that the pressure control unit increases the internal pressure of the decompression room according to the number of the performed substrate processings when two or more substrate processings are successively performed.

In another aspect, the present invention provides a substrate processing method suitable for performing two or more substrate processings successively in which a substrate placed in a chamber is heated by light emitted from a lamp unit provided outside the chamber and introduced through a transmission window constituting a wall of the chamber. In the substrate processing method of the present invention, an internal pressure of the decompression room having a wall constituted by the transmission window at the lamp unit side of the transmission window is set for a specific pressure determined according to the number of performed substrate processings. In this state, a substrate placed in the chamber is processed while being heated by the emitted light.

In this way, the heat accumulation in the transmission window during the successive substrate processings can be reduced, whereby the ambient temperature around the surface of each substrate is fixed in the successive substrate processings. Consequently, the substrates are subject to uniform substrate processing.

With the above structure, the substrate is processed in the chamber under reduced pressure. The internal pressure in the decompression room can be lower than that in the chamber. Furthermore, the internal pressure of the decompression room can be increased according to the number of performed substrate processings.

For example, the substrate can be processed with an oxidizing gas and hydrogen gas being introduced in the chamber to form an oxide on the substrate. In such a case, the total of partial pressures of the oxidizing gas and hydrogen gas is preferably 1 Torr to 50 Torr. Particularly, it is preferable that the oxidizing gas is oxygen gas and water vapor and oxygen radicals are produced in the chamber for oxidization.

According to the present invention, the pressure within the decompression room can be maintained at a specific pressure, controlling the heat radiation rate of the transmission window. Therefore, the heat accumulation in the transmission window during the successive substrate processings can be reduced, whereby the ambient temperature around the surface of each substrate is fixed in the successive substrate processings. Consequently, the substrates are subject to uniform substrate processing.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing a substrate processing apparatus that relates to an embodiment of the present invention.

FIG. 2 is a flowchart of the substrate processing that relates to an embodiment of the present invention.

FIG. 3 is a graphical representation showing the dependencies of the oxide film thickness and the window assembly internal pressure to the number of substrates processed in an embodiment of the present invention.

FIG. 4 is a cross-sectional view showing a modification of the substrate processing apparatus that relates to an embodiment of the present invention.

FIG. 5 is a cross-sectional view showing a prior art substrate processing apparatus.

### DETAILED DESCRIPTION OF PREFERRED EMBODIMENTS

An embodiment of the present invention is described in detail hereafter with reference to the drawings. In the embodiment below, the present invention is realized in forming an oxide film on the surface of a silicon substrate by ISSG oxidization.

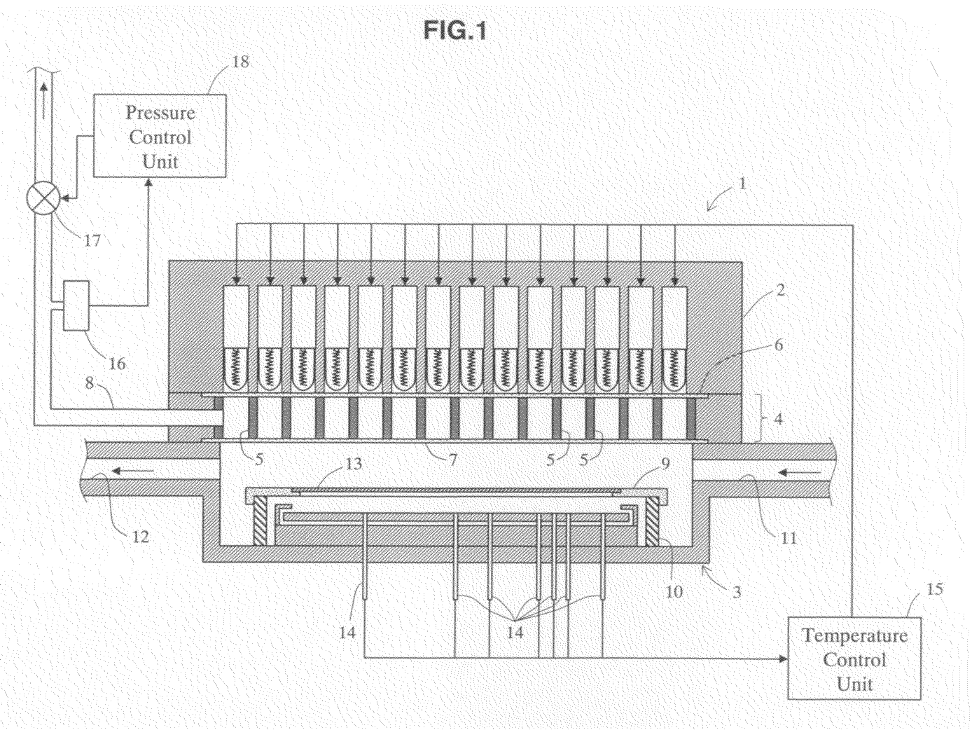

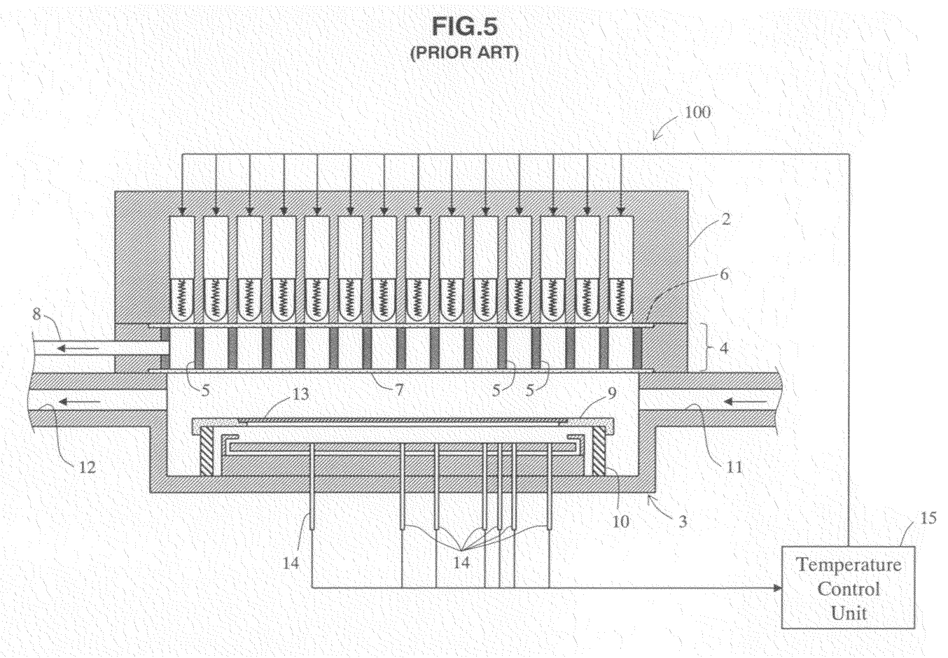

FIG. 1 is a cross-sectional view showing the structure of a substrate processing apparatus in an embodiment of the present invention. In FIG. 1, the same components as in the prior art substrate processing apparatus shown in FIG. 5 are given the same reference numbers and their explanation is omitted in the detailed explanation below.

As shown in FIG. 1, a substrate processing apparatus 1 of this embodiment comprises a lamp unit 2 in which multiple lamps such as tungsten halogen lamps are arranged in one plane above a cylindrical chamber 3 in which the substrate is processed via a window assembly 4 as in the prior art substrate processing apparatus 100.

The chamber 3 is provided with a gas inlet 11 on a sidewall and a gas outlet 12 on the sidewall opposite to the gas inlet 11. A support ring 9 having an inner diameter slightly smaller than the diameter of the substrate 13 to be processed and made of a heat-resistant material such as silicone carbide is arranged in a horizontal plane within the chamber 3. The support ring 9 is supported by a cylindrical rotary cylinder 10. The edge of the substrate 13 rests on the inner fringe of the support ring 9. The rotary cylinder 10 is rotatably supported by the bottom surface of the chamber 3 via a bearing (not shown) in a horizontal plane. The substrate 13 is processed while being rotated.

Multiple radiation temperature sensors 14 consisting of optical fiber probes arranged at proper intervals in a radial direction of the substrate 13 are provided at the bottom of the chamber 3 inside the rotary cylinder 10. The radiation temperature sensors 14 are connected to not-shown thermometers such as pyrometers at the other end. Based on light radiated from the bottom surface of the substrate 13 (radiant heat), the surface temperature of the substrate in process is measured across the substrate from the center to periphery thereof. A temperature control unit 15 controls the output power of the lamps in the lamp unit 2 based on the measurements to achieve uniform temperatures across the substrate from the center to periphery thereof.

The window assembly 4 has a structure comprising multiple optical pipes 5 fixed between an upper quartz plate 6 and a lower quartz plate 7 (transmission window). The optical pipes 5 are arranged at positions corresponding to the respective lamps in the lamp unit 2. The optical pipes 5 transfer light emitted from the respective lamps to the chamber 3 without diffusion. Small grooves (or recesses) are formed on the surfaces of the upper and lower quartz plates 6 and 7 inside the window assembly 4 for communication between the optical pipes 5. Therefore, all optical pipes 5 can be vacuumed by discharging the air through an evacuation duct 8 in communication with one of the optical pipes 5. The space enclosed by the upper and lower quartz plates 6 and 7 and sidewalls of the window assembly 4, including inside spaces of all optical pipes 5, is simply termed the interior of the window assembly 4 (decompression room).

The substrate processing apparatus 1 of this embodiment comprises a pressure control unit 18 for maintaining the internal pressure of the window assembly 4 at a specific pressure as shown in FIG. 1. The pressure control unit 18 can be realized, for example, by a dedicated arithmetic operation circuit, or hardware including a processor and a memory such as a RAM or ROM and software stored in the memory and running on the processor.

The substrate processing apparatus 1 further comprises a variable conductance valve 17 interposed in the evacuation duct 8 and a pressure meter 16 provided to the evacuation duct 8 between the variable conductance valve 17 and the window assembly 4 for measuring the pressure within the evacuation duct 8. The output of the pressure meter 16 is connected to the input of the pressure control unit 18. The pressure control unit 18 changes the opening rate of the variable conductance valve 17 based on the measurements of the pressure meter 16, and the internal pressure of the window assembly 4 is adjusted for a specific pressure as described in detail below. Needless to say, the other end of the evacuation duct 8 is connected to a not-shown vacuum pump. The evacuation system for the evacuation duct 8 is provided separately from the vacuum system for vacuuming the chamber 3.

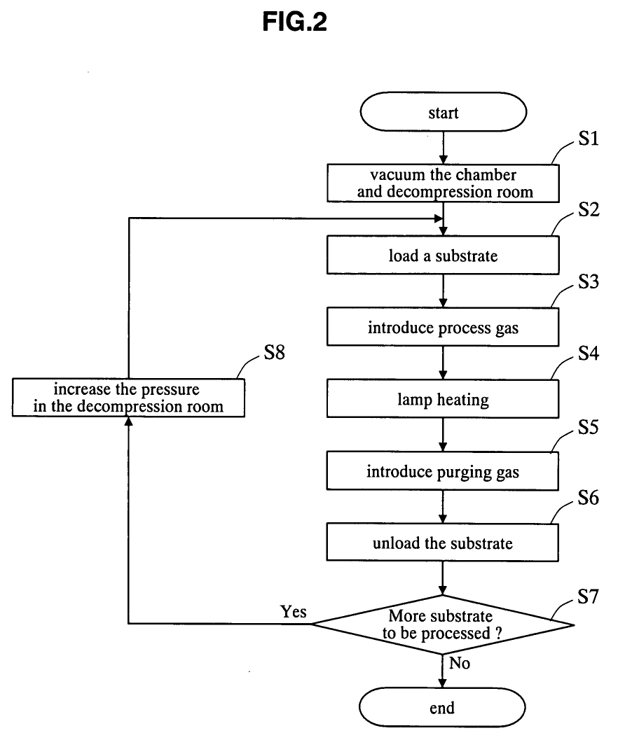

FIG. 2 is a flowchart showing the process of performing two or more substrate processings successively in the substrate processing apparatus 1 having the above structure. As described above, the substrate processing apparatus 1 of this embodiment is a single-wafer type apparatus in which the substrate 13 is processed one by one. Therefore, in this embodiment, the number of performed substrate processings is equal to the number of substrates processed.

As shown in FIG. 2, when the two or more substrate processings is performed successively, first, the chamber 3 is vacuumed to a pressure equal to the pressure for the substrate processing. Meanwhile, the interior of the window assembly 4 is also vacuumed to a pressure equal to the interior of the chamber 3 (Step S1 in FIG. 2). Then, a substrate 13 to be processed is loaded in the chamber 3 and placed on the support ring 9 (Step S2 in FIG. 2). A load-lock chamber is provided outside the substrate gateway for loading/unloading the substrate 13. Therefore, the substrate 13 can be loaded/unloaded while the chamber 3 is vacuumed.

Then, a process gas containing an oxidizing gas and hydrogen gas is introduced into the chamber 3 through the gas inlet 11 (Step S3 in FIG. 2). Here, the interior of the chamber 3 is maintained at a specific pressure at which the substrate processing is performed. In this embodiment, the process gas is a mixed gas of oxygen gas and hydrogen gas and the internal pressure of the chamber 3 is approximately 1 Torr to 50 Torr.

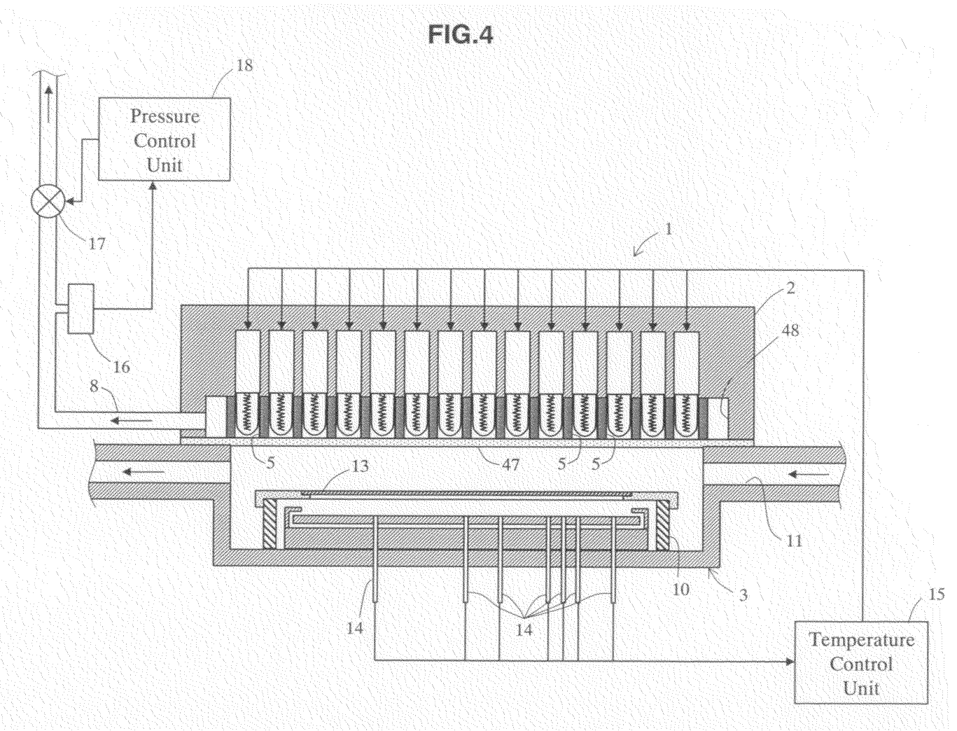

After the pressure within the chamber 3 is stabilized, the lamps in the lamp unit 2 are turned on to heat the substrate 13 on the support ring 9 (Step S4 in FIG. 4). Then, oxygen radicals and H₂O (water vapor) is produced at the surface of the substrate 13, whereby the surface of the substrate 13 is oxidized. The lighting time varies depending on the targeted oxide film thickness. In this embodiment, it is approximately 10 sec to 200 sec. After the lamps are turned off, the interior of the chamber 3 is purged with an inert gas such as argon gas (Step S5 in FIG. 2) and the processed substrate 13 is unloaded from the chamber 3 (Step S6 in FIG. 2). When there are more substrates to be processed after the processed substrate 13 is unloaded, the subsequent substrate to be processed is loaded into the chamber 3 and the above process is repeated (Step S7, Yes→Step 2 in FIG. 2). Here, the pressure control unit 18 increases the internal pressure of the window assembly 4 to a specific pressure according to the number of the substrate processings performed by this time in the successive substrate processings (Step S8 in FIG. 2). In this embodiment, the pressure control unit 18 stores the internal pressure of the window assembly 4 according to the number of the performed substrate processings in the successive substrate processing. For example, if the number of the performed substrate processings is five in the successive substrate processings, the pressure control unit 18 sets the internal pressure of the window assembly 4 for a pressure corresponding to the number of the performed substrate processings being five. Furthermore, in this embodiment, the pressure control unit 18 stores the pressure corresponding to the number of the performed substrate processings. Here, the pressure corresponding to the number of the performed substrate processings is increased by a fixed rate as the number of the performed substrate processings is increased.

On the other hand, when there is no more substrate to be processed after a substrate is processed, the successive substrate processings is completed (Step S7, No in FIG. 2).

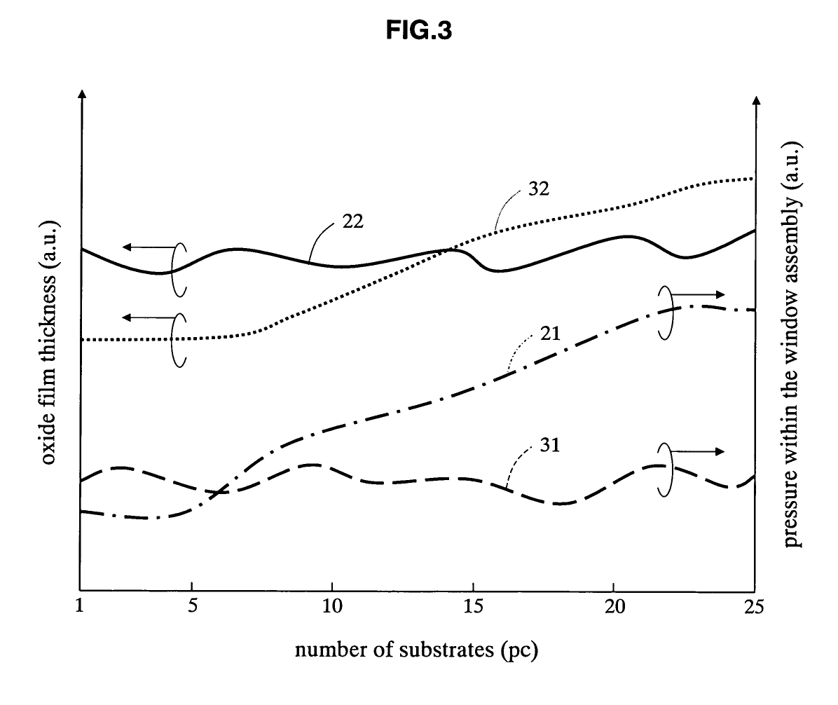

FIG. 3 is a graphical representation showing the oxide film thickness formed on the substrate 13 in each substrate processing and the pressure within the window assembly 4 (output values of the pressure meter 16) in the successive substrate processings as described above. In FIG. 3, the horizontal axis corresponds to the number of substrates (the number of the performed substrate processings), and the left vertical axis corresponds to the oxide film thickness formed on the substrate. In addition, the right vertical axis corresponds to the internal pressure of the window assembly 4 during the each substrate processing. FIG. 3 shows the internal pressure of the window assembly 4 and the oxide film thickness of this embodiment by a single-dotted line 21 and a solid line 22, respectively. FIG. 3 further shows the internal pressure of the window assembly 4 and the oxide film thickness of the prior art by a broken line 31 and a dotted line 32, respectively, for comparison.

As shown in FIG. 3, because of no pressure control in the prior art substrate processing apparatus 100, the pressure 31 within the window assembly 4 is nearly fixed at the capacity limit (for example, 2 Torr or less) of the vacuum pump provided to the evacuation system. In such a case, the lower quartz plate 7 has a low heat radiation rate as described above and accumulates heat according to the number of substrates (the number of the performed substrate processings) due to heat radiated from the components within the chamber 3 (mainly the substrate 13 and support ring 9) in the course of the successive substrate processings. The heat raises the ambient temperature near the surface of the substrate 13 and, consequently, the oxide film formed on each substrate has the thickness 32 increased according to the number of substrates (t the number of the performed substrate processings).

On the other hand, in this embodiment, the pressure control unit 18 increases the pressure 21 within the window assembly 4 according to the number of substrates (the number of the performed substrate processings) each time a substrate is processed. The pressure within the window assembly 4 is adjusted by the pressure control unit 18 controlling the degree of opening/closing of the variable conductance valve 17. Here, the pressure control unit 18 adjusts the pressure detected by the pressure meter 16 shown in FIG. 1 for an optimized pressure with reference to the number of processed substrates. In this way, the heat radiation rate of the lower quartz plate 7 can be increased during the successive substrate processings and the head accumulation within the lower quartz plate 7 due to heat radiated from the components within the chamber 3 (mainly the substrate 13 and support ring 9) is prevented. This is because the pressure within the window assembly 4 is increased, gradually enhancing the heat release by convection of gaseous molecules and reducing the heat accumulation within the components within the chamber 3. Consequently, the ambient temperature within the chamber 3 is raised less and the thickness 22 of the oxide film formed on each substrate has a steady value regardless of the number of substrates (the number of the performed substrate processings).

The oxide films formed as described above exhibit significantly small differences in thickness between the substrates successively processed even if their thickness is approximately 1 to 50 nm. Therefore, they are significantly useful as gate insulating films and sidewall protection oxide films for separating STI (shallow trench isolation) elements.

As shown in FIG. 3, the pressure 21 within the window assembly 4 is desirably increased at any gradient each time a substrate is processed. At what gradient the pressure 21 within the window assembly 4 is increased in the ISSG oxidization during the successive processings is determined according to the target thickness of oxide films formed. The gradient can be determined by preliminary experiments. The internal pressure of the window assembly 4 is not necessarily adjusted for each substrate processing. For example, the internal pressure of the window assembly 4 can be adjusted for multiple processings, e.g. for every other processing.

It is preferable that the pressure within the window assembly 4 be changed from the lower capacity limit of the vacuum pump connected to the evacuation duct 8 (for example, 0.01 Torr) to the pressure within the chamber 3 at which the substrate is processed (for example, 1 to 50 Torr), because if the upper limit of the pressure to be increased exceeds the operation pressure within the chamber 3, the difference in pressure may cause the lower quartz plate 7 to be sucked into the chamber 3 and damaged.

As described above, in this embodiment, the pressure within the window assembly (the decompression room) can be maintained at a specific pressure, enabling the heat radiation rate of the transmission window to be independently changed. Therefore, the heat accumulation within the transmission window during the successive substrate processings is reduced, fixing the ambient temperature around the surface of each substrate while substrates are successively processed. Consequently, the substrates can be subject to uniform substrate processing.

The present invention is not restricted to the above embodiment and various modifications and applications are available within the scope of the efficacy of the present invention. In the above explanation, the pressure within the window assembly 4 is adjusted for a specific pressure according to the number of the performed substrate processings. However, the efficacy of the present invention can be obtained by adjusting the pressure outside the chamber on the side where a chamber wall (transmission window) for introducing light emitted from the lamp unit into the chamber 3 is provided.

For example, when the window assembly 4 is omitted, the structure shown in FIG. 4 can be used. In FIG. 4, a decompression room 48 is provided between the lamps within the lamp unit 2 and a transmission window 47 for introducing light emitted from the lamps into the chamber 3, having a wall constituted by the transmission window 47. The decompression room 48 is built into the lamp unit 2. In the decompression room 48, multiple optical pipes 5 are fixed in positions corresponding to the respective lamps in the lamp unit 2 as in the substrate processing apparatus 1 shown in FIG. 1. Small grooves are formed on the surface of the transmission window 47 that is in contact with the optical pipes 5, enabling the interior of all optical pipes 5 to be vacuumed through the evacuation duct 8 in communication with one of the optical pipes 5. The other structures are the same as in the substrate processing apparatus 1 shown in FIG. 1.

Also in this apparatus, the pressure within the decompression room 48 is adjusted by the pressure control unit 18 according to the number of the performed substrate processings in the successive substrate processings as described above, enabling the heat accumulation within the transmission window during the successive substrate processings to be reduced. Then, the ambient temperature around the surface of each substrate is fixed while substrates are processed in succession. Consequently, the substrates are subject to a uniform substrate processing.

The present invention is not restricted to the substrate processing apparatus involving oxidization and applicable to any substrate processing apparatus for processing substrates while heating them with light emitted from lamps. With the present invention being applied, the substrates are subject to uniform substrate processing when they are processed in succession.

The present invention makes it possible, in successive substrate processings, to prevent the rise in the ambient temperature due to heat accumulation within the transmission window according to the number of the performed substrate processings, and is particularly useful as a substrate processing apparatus and substrate processing method for forming such as ultrathin gate oxide films in succession.

1. An apparatus for processing a substrate, comprising:
a chamber in which a substrate is placed;
a lamp unit heating the substrate placed in the chamber at a position facing the substrate;
a transmission window constituting a wall of the chamber between the chamber and the lamp unit and transmitting light emitted from the lamp unit;
a decompression room having a wall constituted by the transmission window at the lamp unit side of the transmission window;
an evacuation unit vacuuming the interior of the decompression room; and
a pressure control unit controlling the evacuation unit to maintain the pressure within the decompression room at a specific pressure.

2. An apparatus for processing a substrate according to claim 1, wherein the decompression room comprises a wall that transmits light emitted from the lamp unit at the opposing position to the transmission window and the lamp unit is provided on the exterior surface of the wall.

3. An apparatus for processing a substrate according to claim 1, wherein the decompression room is provided within the lamp unit.

4. An apparatus for processing a substrate according to claim 1, wherein the pressure control unit increases an internal pressure of the decompression room according to the number of performed substrate processings when two or more substrate processings are successively performed.

5. An apparatus for processing a substrate according to claim 2, wherein the pressure control unit increases an internal pressure of the decompression room according to the number of performed substrate processings when two or more substrate processings are successively performed.

6. An apparatus for processing a substrate according to claim 3, wherein the pressure control unit increases an internal pressure of the decompression room according to the number of performed substrate processings when two or more substrate processings are successively performed.

7. A method for processing a substrate to perform two or more substrate processings successively in which a substrate placed in a chamber is heated by light emitted from a lamp unit provided outside the chamber and introduced through a transmission window constituting a wall of the chamber, comprising the steps of:
setting an internal pressure of a decompression room having a wall constituted by the transmission window at the lamp unit side of the transmission window for a specific pressure according to the number of performed substrate processings; and
heating the substrate placed in the chamber with the emitted light to perform the substrate processing.

8. A method for processing a substrate according to claim 7, wherein the substrate processing is performed while the interior of the chamber is vacuumed.

9. A method for processing a substrate according to claim 8, wherein the internal pressure of the decompression room is lower than the internal pressure of the chamber.

10. A method for processing a substrate according to claim 7, wherein the internal pressure of the decompression room is increased according to the number of performed substrate processings.

11. A method for processing a substrate according to claim 8, wherein the internal pressure of the decompression room is increased according to the number of performed substrate processings.

12. A method for processing a substrate according to claim 9, wherein the internal pressure of the decompression room is increased according to the number of performed substrate processings.

13. A method for processing a substrate according to claim 9, wherein the substrate processing is a process of forming an oxide on a substrate while introducing a gas containing an oxidizing gas and hydrogen gas into the chamber.

14. A method for processing a substrate according to claim 13, wherein the total of partial pressures of the oxidizing gas and hydrogen gas in the chamber is 1 Torr to 50 Torr.

15. A method for processing a substrate according to claim 13, wherein the oxidizing gas is oxygen gas and water vapor and oxygen radicals are produced in the chamber.
